(19) United States
(12) Patent Application Publication
(10) Pub. No.: US 2018/0308942 A1
(43) Pub. Date: Oct. 25, 2018

(54) MANUFACTURING METHOD OF ELECTRODE LAYER OF TFT SUBSTRATE AND MANUFACTURING METHOD OF FLEXIBLE TFT SUBSTRATE

(71) Applicant: Wuhan China Star Optoelectronics Technology Co., Ltd., Wuhan City (CN)

(72) Inventor: Xing Wang, Wuhan City (CN)

(21) Appl. No.: 15/529,509

(22) PCT Filed: Apr. 11, 2017
(86) PCT No.: PCT/CN2017/080078

§ 371 Date: May 25, 2017

(30) Foreign Application Priority Data
Mar. 9, 2017 (CN) 201710138323.0

(51) Int. Cl. H01L 29/40; H01L 29/786; H01L 29/423; H01L 29/66

(52) U.S. Cl. CPC H01L 29/401; H01L 29/6675; H01L 29/42384; H01L 29/786

(57) ABSTRACT

The present invention provides a manufacturing method of an electrode layer of a TFT substrate and a manufacturing method of a flexible TFT substrate. The manufacturing method of an electrode layer of a TFT substrate according to the present invention first forms a metallic nickel layer on a silicon backing, followed by applying CVD to deposit a graphene layer on the metallic nickel layer and applies plasma etching to etch the graphene layer to form a patterned graphene layer, and finally dissolves away the metallic nickel layer to separate the patterned graphene layer from the silicon backing to allow for transfer of the patterned graphene layer to obtain an electrode layer on a TFT substrate, wherein the electrode layer is formed of a graphene material that has excellent electrical conduction and mechanical properties and also has good thermal stability and chemical stability, so that the manufacturing method realizes production of an electrode layer that suits the need for bending of an electrode layer of a flexible display device.

### BACKGROUND OF THE INVENTION

### 1. Field of the Invention

The present invention relates to the field of display technology, and more particular to a manufacturing method of an electrode layer of a thin-film transistor (TFT) substrate and a manufacturing method of a flexible TFT substrate.

### 2. The Related Arts

In the field of display technology, a flexible display device is a display based on a substrate made of a flexible organic material and showing advantages, such as being thin and light, high contrast, fast response, wide view angle, high brightness, and full color, and can be bent, folded, or even serving as a part of a wearable computer, so as to gain wide applications in special fields, such as portable product with good displaying performance and military applications. Consequently, the flexible display technology is becoming the next generation mainstream display technology.

An active array substrate is a major structural component of a contemporary display, functioning for providing a driving circuit to the display and generally comprising a plurality of gate scanning lines and a plurality of data lines. The plurality of gate scanning lines and the data lines collectively define a plurality of pixel units. Each of the pixel units is provided therein with a thin-film transistor (TFT) and a pixel electrode. The TFT has a gate electrode that is connected to a corresponding one of the gate scanning line so that when a voltage of the gate scanning line reaches a turn-on voltage, a source electrode and a drain electrode are conducted on with each other thereby allowing a data voltage from the data line to feed into the pixel electrode to control displaying a corresponding pixel area. Generally, a structure of the TFTs on the array substrate comprises a gate electrode, a gate insulation layer, an active layer, source and drain electrodes, and insulation protection layer, which are stacked on a backing plate in sequence from bottom to top.

Among the transistors, a low temperature poly-silicon (LTPS) TFT shows a higher electron mobility and is given significant weight to in display techniques, including liquid crystal display (LCD) and organic light emitting diode (OLED) and is regarded as an important material for realizing low cost full color flat panel displaying. Thus, known flexible display devices generally involve an LTPS TFT based array substrate. The gate electrode of the LTPS TFT is generally made of a single layer of metallic molybdenum. Since metallic molybdenum has a high hardness, transgranular fracture often occurs during a flexing process of a flexible display device, leading to an increase of resistivity, and eventually causing problems of slow flowing of electrical currents and transmission delay of signals.

In view of the above problems, it is necessary to provide a manufacturing method of an electrode layer that suits the need for flexible display bending techniques.

### SUMMARY OF THE INVENTION

An objective of the present invention is to provide a manufacturing method of an electrode layer of a thin-film transistor (TFT) substrate for realizing manufacture of an electrode layer that suits the need for bending of a flexible display device.

Another objective of the present invention is to provide a manufacturing method of a flexible TFT substrate, which applies the above manufacturing method of an electrode layer of a TFT substrate to effectively alleviate the technical problem that transgranular fracture readily occurs in a bending process of a conventional flexible display device and thus leads to an increase of resistivity.

To achieve the above objectives, the present invention provides a manufacturing method of an electrode layer of a TFT substrate, which comprises the following steps:

Step 1: providing a silicon backing and forming a metallic nickel layer on the silicon backing;

Step 2: applying chemical vapor deposition to deposit a graphene layer on the metallic nickel layer and applying plasma etching to etch the graphene layer so as to form a patterned graphene layer; and

Step 3: removing the metallic nickel layer that is located on the silicon backing through dissolution so as to separate the patterned graphene layer from the silicon backing and then transferring the patterned graphene layer to form an electrode layer on a TFT substrate.

The metallic nickel layer formed in Step 1 has a thickness of 10-50 nm.

The graphene layer formed in Step 2 through deposition has a thickness of 5-10 nm.

Alignment marking is applied in Step 3 for position-aligned transfer of the patterned graphene layer.

The TFT substrate comprises a flexible low temperature poly-silicon TFT substrate.

The electrode layer formed in Step 3 comprises a gate electrode of the TFT substrate.

The present invention also provides a manufacturing method of a flexible TFT substrate, which comprises the following steps:

Step 10: providing a glass plate and forming a flexible substrate on the glass plate;

Step 20: forming, in sequence, a buffer layer, an active layer, and a gate insulation layer on the flexible substrate;

Step 30: providing a silicon backing and forming a metallic nickel layer on the silicon backing; applying chemical vapor deposition to deposit a graphene layer on the metallic nickel layer and applying plasma etching to etch the graphene layer so as to form a patterned graphene layer; and removing the metallic nickel layer that is located on the silicon backing through dissolution so as to separate the patterned graphene layer from the silicon backing, and then, transferring the patterned graphene layer to the gate insulation layer to form a gate electrode layer; and

Step 40: forming, in sequence, an interlayer insulation layer and a source and drain metal layer on the gate insulation layer and the gate electrode layer.

The flexible TFT substrate comprises a low temperature poly-silicon TFT substrate;

the flexible substrate formed in Step 10 comprises a polyimide substrate, which has a thickness of 10-20 μm;

the buffer layer, the active layer, and the gate insulation layer formed in Step 20 respectively have thicknesses of 200-300 nm, 40-50 nm, and 50-200 nm; and

the interlayer insulation layer and the source and drain metal layer formed in Step 40 respectively have thicknesses of 500-700 nm and 400-600 nm.

In Step 30, the metallic nickel layer so formed has a thickness of 10-50 nm and the graphene layer so formed through deposition has a thickness of 5-10 nm.

In Step 30, alignment marking is applied for position-aligned transfer of the patterned graphene layer to the gate insulation layer.

The present invention further provides a manufacturing method of an electrode layer of a TFT substrate, which comprises the following steps:

Step 1: providing a silicon backing and forming a metallic nickel layer on the silicon backing;

Step 2: applying chemical vapor deposition to deposit a graphene layer on the metallic nickel layer and applying plasma etching to etch the graphene layer so as to form a patterned graphene layer; and

Step 3: removing the metallic nickel layer that is located on the silicon backing through dissolution so as to separate the patterned graphene layer from the silicon backing and then transferring the patterned graphene layer to form an electrode layer on a TFT substrate;

wherein the metallic nickel layer formed in Step 1 has a thickness of 10-50 nm; and

wherein the graphene layer formed in Step 2 through deposition has a thickness of 5-10 nm.

The efficacy of the present invention is that the present invention provides a manufacturing method of an electrode layer of a TFT substrate, which first forms a metallic nickel layer on a silicon backing, followed by applying CVD to deposit a graphene layer on the metallic nickel layer and applies plasma etching to etch the graphene layer to form a patterned graphene layer, and finally dissolves away the metallic nickel layer to separate the patterned graphene layer from the silicon backing to allow for transfer of the patterned graphene layer to obtain an electrode layer on a TFT substrate, wherein the electrode layer is formed of a graphene material that has excellent electrical conduction and mechanical properties and also has good thermal stability and chemical stability, so that the manufacturing method realizes production of an electrode layer that suits the need for bending of an electrode layer of a flexible display device. The present invention provides a manufacturing method of a flexible TFT substrate, which applies the above-described manufacturing method of an electrode layer of a TFT substrate to form a gate electrode layer, so as to effectively alleviate the technical problem that transgranular fracture readily occurs in a bending process of a conventional flexible display device and thus leads to an increase of resistivity.

### BRIEF DESCRIPTION OF THE DRAWINGS

For better understanding of the features and technical contents of the present invention, reference will be made to the following detailed description of the present invention and the attached drawings. However, the drawings are provided only for reference and illustration and are not intended to limit the present invention.

In the drawings:

FIG. 1 is a flow chart illustrating a manufacturing method of an electrode layer of a thin-film transistor (TFT) substrate according to the present invention;

FIG. 2 is a schematic view illustrating Step 1 of the manufacturing method of an electrode layer of a TFT substrate according to the present invention;

FIGS. 3 and 4 are schematic views illustrating Step 2 of the manufacturing method of an electrode layer of a TFT substrate according to the present invention;

FIG. 5 is a schematic view illustrating Step 3 of the manufacturing method of an electrode layer of a TFT substrate according to the present invention;

FIG. 6 is a flow chart illustrating a manufacturing method of a flexible TFT substrate according to the present invention;

FIG. 7 is a schematic view illustrating Step 10 of the manufacturing method of a flexible TFT substrate according to the present invention;

FIG. 8 is a schematic view illustrating Step 20 of the manufacturing method of a flexible TFT substrate according to the present invention;

FIG. 9 is a schematic view illustrating Step 30 of the manufacturing method of a flexible TFT substrate according to the present invention; and

FIG. 10 is a schematic view illustrating Step 40 of the manufacturing method of a flexible TFT substrate according to the present invention.

### DETAILED DESCRIPTION OF THE PREFERRED EMBODIMENTS

To further expound the technical solution adopted in the present invention and the advantages thereof, a detailed description will be given with reference to the preferred embodiments of the present invention and the drawings thereof.

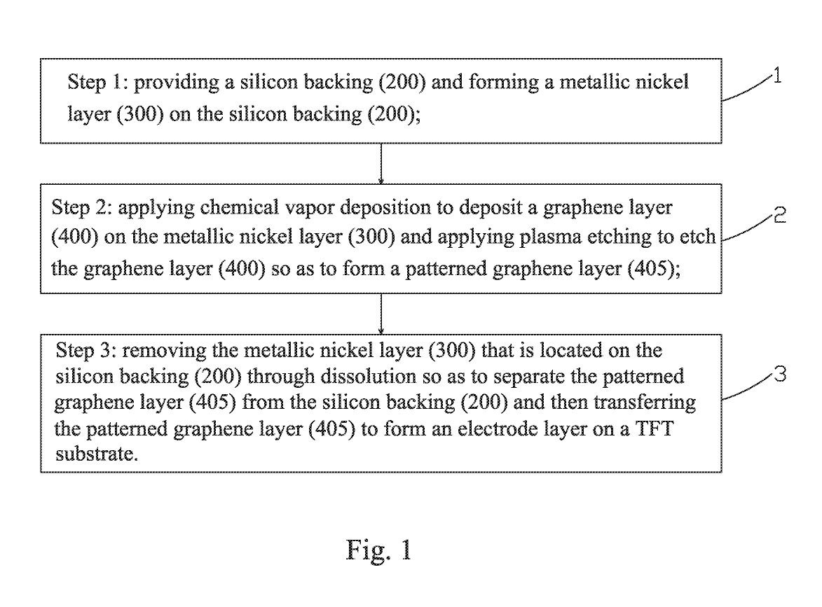

Referring to FIG. 1, firstly, the present invention provides a manufacturing method of an electrode layer of a thin-film transistor (TFT) substrate, comprising the following steps:

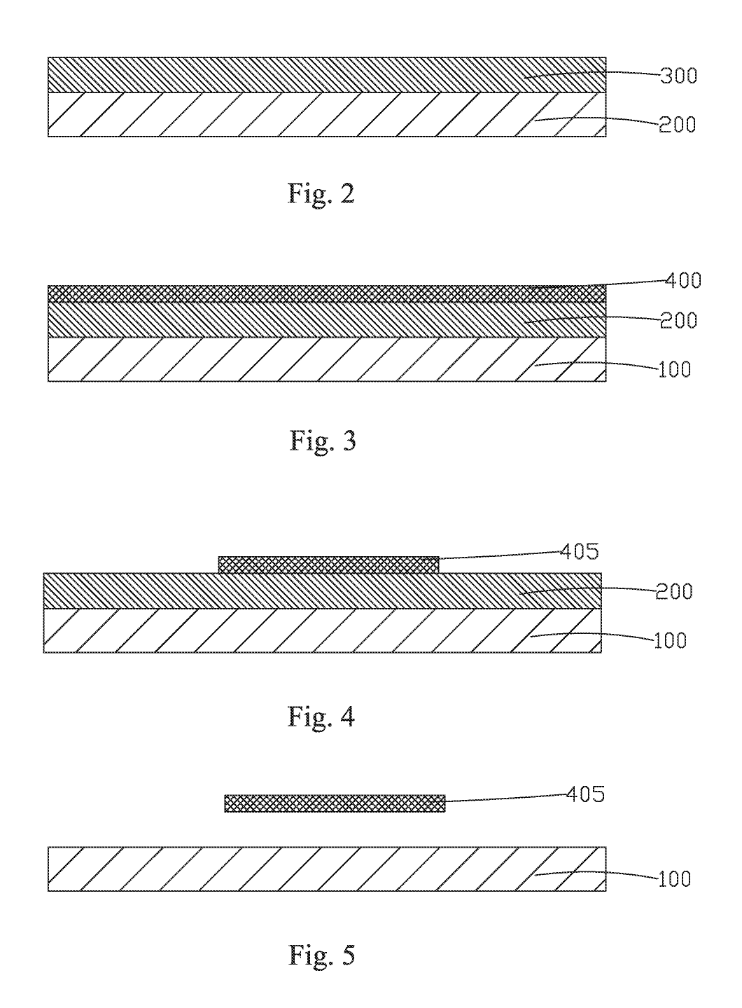

Step 1: as shown in FIG. 2, providing a silicon backing 200 and forming a metallic nickel layer 300 on the silicon backing 200.

Specifically, in Step 1, the metallic nickel layer 300 so formed has a thickness of 10-50 nm.

Step 2: as shown in FIG. 3, applying chemical vapor deposition (CVD) to deposit a graphene layer 400 on the metallic nickel layer 300, and as shown in FIG. 4, applying plasma etching to etch the graphene layer 400 so as to form a patterned graphene layer 405.

Specifically, in Step 2, the graphene layer 400 so formed through deposition has a thickness of 5-10 nm.

Specifically, in Step 2, plasma enhanced chemical vapor deposition (PECVD) is adopted to deposit and thus form the graphene layer 400.

Step 3: as shown in FIG. 5, removing the metallic nickel layer 300 that is located on the silicon backing 200 through dissolution so as to separate the patterned graphene layer 405 from the silicon backing 200 and then transferring the patterned graphene layer 405 to form an electrode layer on a TFT substrate.

Specifically, in Step 3, alignment marking is applied for position-aligned transfer of the patterned graphene layer 405.

Specifically, in Step 3, a diluted nitric acid solution is used to dissolve and remove the metallic nickel layer 300.

Specifically, the TFT substrate is a flexible low temperature poly-silicon TFT substrate.

Specifically, in Step 3, the electrode layer so formed is a gate electrode layer of a TFT substrate.

Graphene has excellent electrical conduction and mechanical properties and also has good thermal stability and chemical stability, and in addition, a graphene film can be made through chemical vapor deposition and patterned through plasma etching. Thus, the manufacturing method of an electrode layer of a TFT substrate according to the present invention allows formation of an electrode layer that suits the need of bending of a flexible display device by taking the steps of forming a metallic nickel layer 300 on a silicon backing 200, followed by depositing and etching a graphene layer 400 on the metallic nickel layer 300 to form a patterned graphene layer 405, and finally dissolving away the metallic nickel layer 300 and proceeding with transfer of the patterned graphene layer 405 to thereby obtain an electrode layer on a TFT substrate.

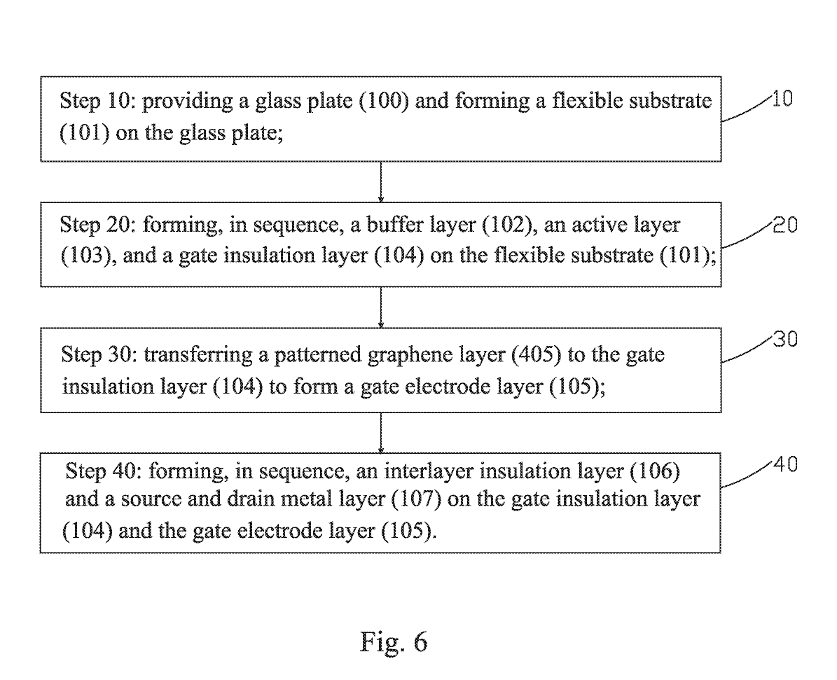

Referring to FIG. 6, based on the above-described manufacturing method of an electrode layer of a TFT substrate, the present invention also provides a manufacturing method of a flexible TFT substrate, to which the above-described method is applicable, comprising specifically the following steps:

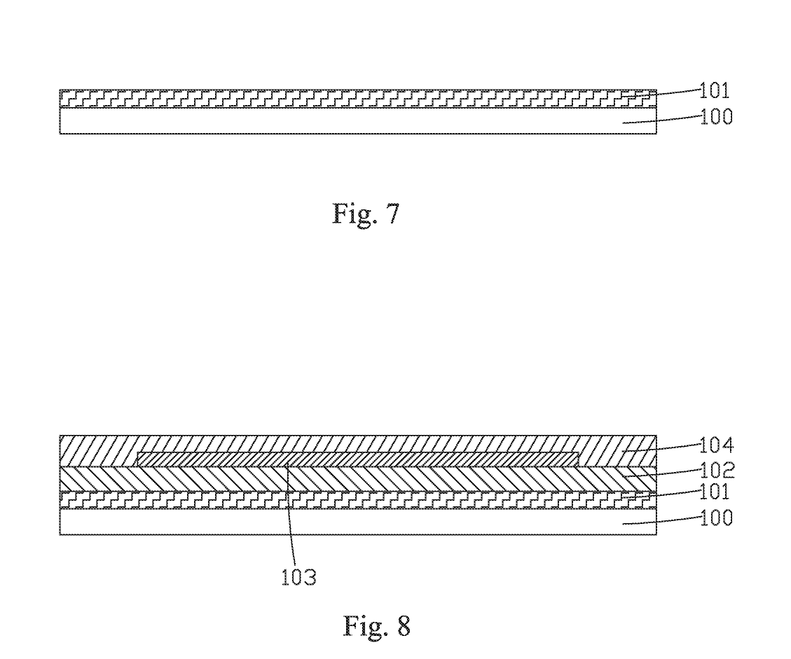

Step 10: as shown in FIG. 7, providing a glass plate 100 and forming a flexible substrate 101 on the glass plate 100.

Specifically, in Step 10, the flexible substrate 101 so formed is a polyimide substrate, which has a thickness of 10-20 μm.

Step 20: as shown in FIG. 8, forming, in sequence, a buffer layer 102, an active layer 103, and a gate insulation layer 104 on the flexible substrate 101.

Specifically, in Step 20, the buffer layer 102, the active layer 103, and the gate insulation layer 104 so formed have thickness of 200-300 nm, 40-50 nm, and 50-200 nm, respectively.

Specifically, the flexible TFT substrate is a flexible low temperature poly-silicon TFT substrate; and the active layer 103 is formed of a material comprising low temperature poly-silicon.

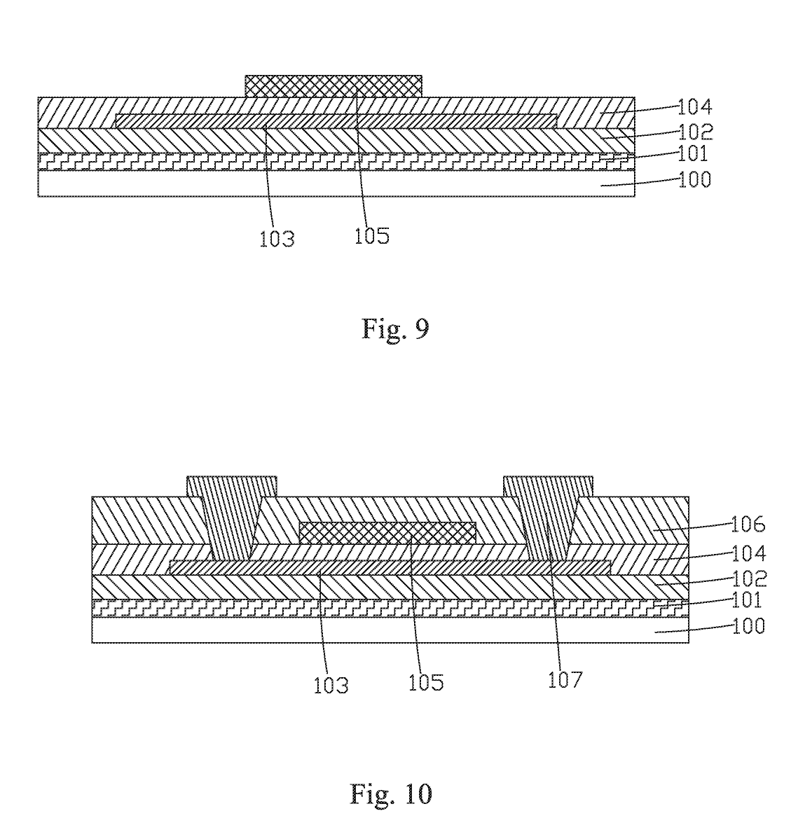

Step 30: as shown in FIG. 9, in combination with FIGS. 2-5, providing a silicon backing 200 and forming a metallic nickel layer 300 on the silicon backing 200; applying CVD to deposit a graphene layer 400 on the metallic nickel layer 300 and applying plasma etching to etch the graphene layer 400 so as to form a patterned graphene layer 405; and removing the metallic nickel layer 300 that is located on the silicon backing 200 through dissolution so as to separate the patterned graphene layer 405 from the silicon backing 200, and then, transferring the patterned graphene layer 405 to the gate insulation layer 104 to form a gate electrode layer 105.

Specifically, in Step 30, the metallic nickel layer 300 so formed has a thickness of 10-50 nm, and the graphene layer 400 so formed through deposition has a thickness of 5-10 nm.

Specifically, in Step 30, alignment marking is applied for position-aligned transfer of the patterned graphene layer 405 to the gate insulation layer 104.

Specifically, in Step 300, a diluted nitric acid solution is used to dissolve and remove the metallic nickel layer 300.

Step 40: as shown in FIG. 10, forming, in sequence, an interlayer insulation layer 106 and a source and drain metal layer 107 on the gate insulation layer 104 and the gate electrode layer 105.

Specifically, in Step 40, the interlayer insulation layer 106 and the source and drain metal layer 107 so formed have thicknesses of 500-700 nm and 400-600 nm, respectively.

In the manufacturing method of a flexible TFT substrate according to the present invention, since a material that is used to form the gate electrode layer 105 in Step 30, in which comprises graphene that has excellent electrical conduction and mechanical properties and also has good thermal stability and chemical stability so that the technical problem that transgranular fracture readily occurs in a bending process of a conventional flexible display device that includes a gate electrode layer made of metallic molybdenum and thus leads to an increase of resistivity could be effectively alleviated.

In summary, the present invention provides a manufacturing method of an electrode layer of a TFT substrate, which first forms a metallic nickel layer on a silicon backing, followed by applying CVD to deposit a graphene layer on the metallic nickel layer and applies plasma etching to etch the graphene layer to form a patterned graphene layer, and finally dissolves away the metallic nickel layer to separate the patterned graphene layer from the silicon backing to allow for transfer of the patterned graphene layer to obtain an electrode layer on a TFT substrate, wherein the electrode layer is formed of a graphene material that has excellent electrical conduction and mechanical properties and also has good thermal stability and chemical stability, so that the manufacturing method realizes production of an electrode layer that suits the need for bending of an electrode layer of a flexible display device. The present invention provides a manufacturing method of a flexible TFT substrate, which applies the above-described manufacturing method of an electrode layer of a TFT substrate to form a gate electrode layer, so as to effectively alleviate the technical problem that transgranular fracture readily occurs in a bending process of a conventional flexible display device and thus leads to an increase of resistivity.

Based on the description given above, those having ordinary skills in the art may easily contemplate various changes and modifications of he technical solution and the technical ideas of the present invention. All these changes and modifications are considered belonging to the protection scope of the present invention as defined in the appended claims.

What is claimed is:

1. A manufacturing method of an electrode layer of a thin-film transistor (TFT) substrate, comprising the following steps:
Step 1: providing a silicon backing and forming a metallic nickel layer on the silicon backing;
Step 2: applying chemical vapor deposition to deposit a graphene layer on the metallic nickel layer and applying plasma etching to etch the graphene layer so as to form a patterned graphene layer; and
Step 3: removing the metallic nickel layer that is located on the silicon backing through dissolution so as to separate the patterned graphene layer from the silicon backing and then transferring the patterned graphene layer to form an electrode layer on a TFT substrate.

2. The manufacturing method of an electrode layer of a TFT substrate as claimed in claim 1, wherein the metallic nickel layer formed in Step 1 has a thickness of 10-50 nm.

3. The manufacturing method of an electrode layer of a TFT substrate as claimed in claim 1, wherein the graphene layer formed in Step 2 through deposition has a thickness of 5-10 nm.

4. The manufacturing method of an electrode layer of a TFT substrate as claimed in claim 1, wherein alignment marking is applied in Step 3 for position-aligned transfer of the patterned graphene layer.

5. The manufacturing method of an electrode layer of a TFT substrate as claimed in claim 1, wherein the TFT substrate comprises a flexible low temperature poly-silicon TFT substrate.

6. The manufacturing method of an electrode layer of a TFT substrate as claimed in claim 1, wherein the electrode layer formed in Step 3 comprises a gate electrode of the TFT substrate.

7. A manufacturing method of a flexible thin-film transistor (TFT) substrate, comprising the following steps:
Step 10: providing a glass plate and forming a flexible substrate on the glass plate;
Step 20: forming, in sequence, a buffer layer, an active layer, and a gate insulation layer on the flexible substrate;
Step 30: providing a silicon backing and forming a metallic nickel layer on the silicon backing; applying chemical vapor deposition to deposit a graphene layer on the metallic nickel layer and applying plasma etching to etch the graphene layer so as to form a patterned graphene layer; and removing the metallic nickel layer that is located on the silicon backing through dissolution so as to separate the patterned graphene layer from the silicon backing, and then, transferring the patterned graphene layer to the gate insulation layer to form a gate electrode layer; and
Step 40: forming, in sequence, an interlayer insulation layer and a source and drain metal layer on the gate insulation layer and the gate electrode layer.

8. The manufacturing method of a flexible TFT substrate as claimed in claim 7, wherein the flexible TFT substrate comprises a low temperature poly-silicon TFT substrate;
the flexible substrate formed in Step 10 comprises a polyimide substrate, which has a thickness of 10-20 μm;
the buffer layer, the active layer, and the gate insulation layer formed in Step 20 respectively have thicknesses of 200-300 nm, 40-50 nm, and 50-200 nm; and
the interlayer insulation layer and the source and drain metal layer formed in Step 40 respectively have thicknesses of 500-700 nm and 400-600 nm.

9. The manufacturing method of a flexible TFT substrate as claimed in claim 7, wherein in Step 30, the metallic nickel layer so formed has a thickness of 10-50 nm and the graphene layer so formed through deposition has a thickness of 5-10 nm.

10. The manufacturing method of a flexible TFT substrate as claimed in claim 7, wherein in Step 30, alignment marking is applied for position-aligned transfer of the patterned graphene la

11. A manufacturing method of an electrode layer of a thin-film transistor (TFT) substrate, comprising the following steps:
Step 1: providing a silicon backing and forming a metallic nickel layer on the silicon backing;
Step 2: applying chemical vapor deposition to deposit a graphene layer on the metallic nickel layer and applying plasma etching to etch the graphene layer so as to form a patterned graphene layer; and
Step 3: removing the metallic nickel layer that is located on the silicon backing through dissolution so as to separate the patterned graphene layer from the silicon backing and then transferring the patterned graphene layer to form an electrode layer on a TFT substrate;
wherein the metallic nickel layer formed in Step 1 has a thickness of 10-50 nm; and
wherein the graphene layer formed in Step 2 through deposition has a thickness of 5-10 nm.

12. The manufacturing method of an electrode layer of a TFT substrate as claimed in claim 11, wherein alignment marking is applied in Step 3 for position-aligned transfer of the patterned graphene layer.

13. The manufacturing method of an electrode layer of a TFT substrate as claimed in claim 11, wherein the TFT substrate comprises a flexible low temperature poly-silicon TFT substrate.

14. The manufacturing method of an electrode layer of a TFT substrate as claimed in claim 11, wherein the electrode layer formed in Step 3 comprises a gate electrode of the TFT substrate.
